(19) United States
(12) Patent Application Publication
(10) Pub. No.: US 2005/0050503 A1
(43) Pub. Date: Mar. 3, 2005

(54) Systems and methods for establishing data model consistency of computer aided design tools

(76) Inventors: S. Brandon Keller, Evans, CO (US); Gregory Dennis Rogers, Fort Collins, CO (US); George Harold Robbert, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/647,769

(22) Filed: Aug. 25, 2003

(51) Int. Cl. G06F 17/50; H03K 19/00; G06F 17/30

(52) U.S. Cl. 716/11; 716/4; 716/17; 707/203

(57) ABSTRACT

A method and system for establishing consistency, with respect to a data model, between sub-modules within an E-CAD tool. A consistency database, including at least one consistency indicator for each block of interest in the data model, is initially created. One or more of the sub-modules is then executed to perform an analysis of a current version of the data model. At least one data field value, corresponding to the consistency indicator, is compared for each block of interest, in source files in the current version of the data model being analyzed, against a corresponding consistency indicator in the consistency database. A warning is issued, indicating a possible discrepancy between data in the current version of the data model and corresponding data in a previous version of the data model, if a difference is detected between at least one data field value in the current version of the data model being analyzed and the corresponding consistency indicator.

### BACKGROUND

Users of E-CAD (electronic computer-aided design) tools may encounter unexpected results when changes are made to a VLSI data model while the model is being analyzed. Typically, E-CAD tools do not check for data consistency between the subsequent execution of different sub-tools during a given analysis of a data model. The assumption is generally made that VLSI design engineers responsible for the data model will not make changes to the model while an analysis is being run. Frequently, however, a data model is, in fact, modified during an analysis run, resulting in unexpected behavior and anomalous output from an analysis tool. Valuable design engineer time and resources may thus be spent in attempting to determine the cause of the unexpected and/or anomalous results. What is needed is a method of ensuring that an E-CAD tool will not produce unreliable results when a data model under analysis is modified during the analysis. Alternatively, the source data can be locked down while analyzing it, to guarantee that changes cannot be made during analysis. This alternative is, of course, disadvantageous because it precludes the designers from making progress on the design of the chip while an analysis is underway.

### SUMMARY

A disclosed embodiment includes a system for establishing consistency, with respect to a data model, between sub-modules within an E-CAD tool. A consistency database, including at least one consistency indicator for each block of interest in the data model, is initially created. One or more of the sub-modules is then executed to perform an analysis of a current version of the data model. At least one data field value, corresponding to the consistency indicator, is compared for each block of interest, in source files in the current version of the data model being analyzed, against a corresponding consistency indicator in the consistency database. A warning is issued, indicating a possible discrepancy between data in the current version of the data model and corresponding data in a previous version of the data model, if a difference is detected between at least one data field value in the current version of the data model being analyzed and the corresponding consistency indicator.

### BRIEF DESCRIPTION OF THE DRAWINGS

A more complete understanding of the present system and method may be obtained by reference to the drawings, in which:

FIG. 1 shows an exemplary embodiment of a data model consistency system; and

FIG. 2 is a flowchart illustrating an exemplary set of steps performed in operation of the system of FIG. 1.

### DETAILED DESCRIPTION

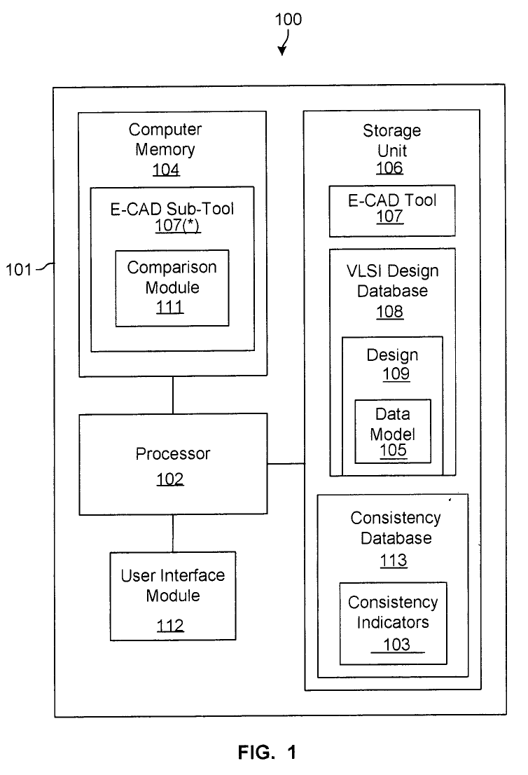

FIG. 1 shows an exemplary embodiment of a data model consistency system 100 configured for establishing data model consistency across one or more modules within a multiple-program E-CAD (electronic computer-aided design) tool 107. Data model consistency system 100 includes computer system 101 and E-CAD tool 107. Computer system 101 operatively controls E-CAD sub-tool 107(*) to analyze VLSI circuit design 109. Computer system 101 includes processor 102, computer memory 104, and storage unit 106. In an exemplary embodiment, comparison module 111 is integrated into one or more of the circuit analysis programs, or ‘sub-tools’ 107(*), which are sub-modules of E-CAD tool 107, and which initially reside in storage unit 106. Comparison module 111 may, optionally, be a stand-alone (functionally independent) module invoked from E-CAD sub-tool 107(*).

Upon initialization, E-CAD sub-tool 107(*) is loaded into computer memory 104. Processor 102 executes comparison module 111 as part of the set of E-CAD instructions being executed by sub-tool 107(*). At least part of the circuit design 109 under analysis is also loaded in computer memory 104. Design 109 includes a data model 105, which comprises various components that are modified from time to time during the analysis of the design. In an exemplary embodiment, system 100 includes a user interface module 112 that is used for indicating a difference between consistency data (described below) in data model 105 and corresponding consistency data in database 113 determined by a previous analysis.

In an exemplary embodiment, comparison module 111 is configured for reading and comparing consistency indicators 103, including timestamp and other optional consistency data in data model 105, against data stored in a consistency database 113 containing similar-type information determined by a previous analysis of the data model. Comparison module 111 queries consistency database 113 to ensure that the design data in data model 105 is unchanged since that particular data model was last updated in consistency database 113. If there are any discrepancies in the consistency information between data model 105 and consistency database 113, user interface module 112 issues a warning to a user to indicate the possible inaccuracy of results due to design data inconsistency.

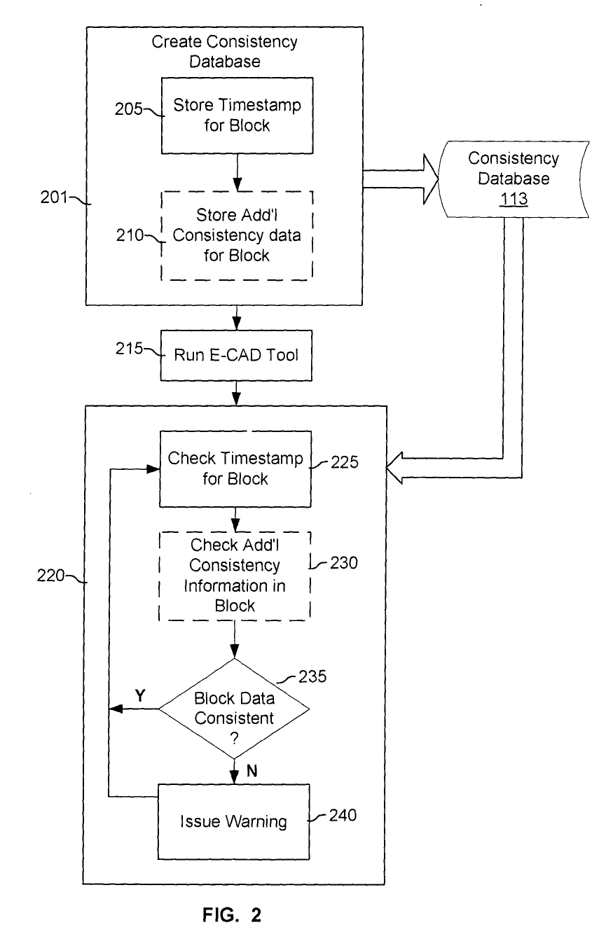

FIG. 2 is a flowchart illustrating an exemplary set of steps performed in operation of the system of FIG. 1. As shown in FIG. 2, the steps in section 201 are performed for each block (i.e., a hierarchical block of the circuit design 109) of interest in data model 105 to create consistency database 113, which is the comparison standard against which subsequent versions of data model 105 are checked for consistency. Data model 105 is a subset of VLSI circuit design 109. In section 201, which comprises the initial phase of the present method, Comparison module 111 generates consistency database 113 by storing consistency data therein including consistency indicators 103 for each block of interest in data model 105, along with other data (e.g., source files) relating to design 109. Each consistency indicator 103 comprises a specific data field associated with a block in a ‘baseline’ version of data model 105. In an exemplary embodiment, comparison module 111 is integrated into one or more analysis sub-tools. Alternatively, comparison module 111 may be used as a stand-alone ‘consistency checking’ tool.

In step 205, comparison module 111 stores, in consistency database 113, one or more of the consistency indicators 103 comprising timestamp values in the source file for each block in the baseline data model 105, as determined during a previous analysis of the block. A new consistency database 113 is created for each run of each analysis tool 107, which may have multiple modules (sub-tools) 107(*) that all access the same consistency database 113 and source files. The consistency indicators 103 that are stored in step 205 include timestamp information which indicates the time of creation or last modification of a file containing data for a particular block in data model 105. More specifically, this timestamp information includes the processor machine time, and optionally, the date and/or the 24 hour clock time.

At step 210, additional consistency indicators 103, such as the file size of source files in a data model 105, may also be stored in consistency database 113 for each block of interest in the data model.

An example of the types of data that may be stored in consistency database 113 is indicated below in Table 1.

TABLE 1
SAMPLE CONSISTENCY DATABASE

| Blockname | DataType | RepType | |
|---|---|---|---|
| BdlFile | BdlDate | BdlTime | BdlMachTime |
| mmudecodeasl | wire_cap | artrc | |
| rcld/cap.nom | 06/06/2003 | 20:32:41 | 1023417161 |
| mmudecodeasl | fet_cap | artrc | |
| rcld/cap.nom | 06/06/2003 | 20:32:41 | 1023417161 |
| mmudecodeasl | connect. | art | |
| conn/bdl.out | 06/20/2003 | 09:56:02 | 1024588562 |
| mmudecodeasl | leakage | art | |
| conn/bdl.out | 06/20/2003 | 09:56:02 | 1024588562 |

As shown in the Sample Consistency Database of Table 1, each file under the heading ‘BdlFile’ is the name of the source file that contains the various types of data (e.g., wire capacitance [‘wire_cap’] data) indicated by the table entries under the heading ‘DataType’. E-CAD tool 107 or sub-tools 107(*) also use the ‘DataType’ and, in addition, the ‘RepType’ (data source, e.g., artwork) information in consistency database 113 to determine the files to be used for analysis of data model 105. The entries in Table 1 indicated as ‘BdlMachTime’, ‘BdlDate’, and ‘BdlTime’ are consistency indicators 103 that represent the respective processor machine time, the date, and the 24 hour clock time when the associated ‘BdlFile’ file was either created or last modified.

In step 215, at least one sub-tool 107(*) of E-CAD tool 107 is run (executed by processor 102) to analyze a current version of data model 105 by performing the steps in section 220 for each block of interest in the data model. In step 225, a presently running sub-tool 107(*) causes an integrated (or associated) comparison module 111 to be executed. Comparison module 111 then compares data field values comprising timestamp values for each block of interest, in source files in the data model 105 presently being analyzed, against timestamp consistency indicators 103 in consistency database 113. More specifically, using the nomenclature in the Sample Consistency Database of Table 1, data fields representing BdlMachTime, and optionally, BdlDate, and BdlTime, in source BdlFile in data model 105, are checked against the corresponding consistency indicators 103 in consistency database 113. In an exemplary embodiment, these ‘corresponding consistency indicators’ 103 are the corresponding identical fields in the data model 105 presently being analyzed. A plurality of sub-tools 107(*) may be simultaneously operational, in which case, the present system 100 provides a mechanism of detecting modifications made to data model 105 by a sub-tool 107(*) other than the one which may be currently executing comparison module 111.

In step 230, which is optional in one embodiment, additional consistency data, such as the file size of source files in a data model 105, may also be compared to corresponding consistency indicators 103 in consistency database 113.

In step 235, comparison module 111 further processes each block in response to the comparison of the block data made in step 225, and optionally, in response to the comparison made in step 230, if additional consistency data was stored in consistency database 113 in step 210. If a timestamp or other inconsistency between the current data model 105 and consistency database 113 is found with respect to one or more consistency indicators 103, user interface module 112 issues a warning indicating a possible data discrepancy between the current data model 105 and a previous version of the data model in step 240. For example, the warning produced by interface module 112 may alert a user that a particular block in data model 105 should be recalculated or reanalyzed by E-CAD tool 107 or sub-tool 107(*).

Instructions that perform the operation discussed with respect to FIG. 2 may be stored on computer-readable storage media. These instructions may be retrieved and executed by a processor, such as processor 102 of FIG. 1, to direct the processor to operate in accordance with the present system. The instructions may also be stored in firmware. Examples of storage media include memory devices, tapes, disks, integrated circuits, and servers.

Certain changes may be made in the above methods and systems without departing from the scope of the present system. It is to be noted that all matter contained in the above description or shown in the accompanying drawings is to be interpreted as illustrative and not in a limiting sense. For example, the items shown in FIG. 1 may be constructed, connected, arranged, and/or combined in other configurations, and the set of steps illustrated in FIG. 2 may be performed in a different order than shown without departing from the spirit hereof.

1. A method for establishing consistency, with respect to a data model, between sub-modules within an E-CAD tool, comprising the steps of:
creating a consistency database including at least one consistency indicator for each block of interest in the data model;
executing one of the sub-modules to perform an analysis of a current version of the data model;
comparing at least one data field value corresponding to said consistency indicator, for each block of interest, in source files in the current version of the data model being analyzed, against a corresponding said consistency indicator in the consistency database; and
issuing a warning indicating a possible discrepancy between data in the current version of the data model and corresponding said data in a previous said version of the data model, in response to detecting a difference between said at least one data field value in the current version of the data model being analyzed and the corresponding said consistency indicator.

2. The method of claim 1, wherein the consistency indicator comprises timestamp information indicating a time of creation of one of the source files.

3. The method of claim 2, wherein the consistency indicator further comprises additional information indicating file sizes of the source files in the data model.

4. The method of claim 1, wherein a plurality of the sub-modules are simultaneously operational.

5. A method for establishing consistency, with respect to a data model, between sub-modules within an E-CAD tool, comprising the steps of:
creating a consistency database including at least one consistency indicator for each block of interest in the data model;
executing one of the sub-modules to perform an analysis of a current version of the data model;
comparing a data field value corresponding to said consistency indicator, for each block of interest, in source files in the current version of the data model being analyzed, against a corresponding said consistency indicator in the consistency database;
wherein the consistency indicator comprises timestamp information indicating either a time of creation or a time of modification of one of the source files; and
issuing a warning indicating a possible discrepancy between data in the version of the data model being analyzed and corresponding said data in a previous said version of the data model, in response to detecting a difference between said data field value in the current version of the data model being analyzed and the corresponding said consistency indicator.

6. The method of claim 5, wherein the consistency indicator further comprises additional information indicating file sizes of the source files in the data model.

7. A system for establishing consistency, with respect to a data model, between sub-modules within an E-CAD tool, comprising:
a processor;
a consistency database, accessible by the processor, for storing consistency information for each block of interest in the data model;
a comparison module, capable of accessing the consistency database and executable via said processor, for comparing at least one data field value, corresponding to said consistency information, against corresponding said consistency information in the consistency database;
and
an interface module, responsive to comparison of a difference between said data field value in a current version of the data model being analyzed and a corresponding said consistency information, for issuing a warning indicating a possible discrepancy between data in the current version of the data model and corresponding said data in a previous said version of the data model.

8. The system of claim 7, wherein the consistency information comprises timestamp information indicating a time of modification of one of the source files.

9. The system of claim 8, wherein the consistency information further comprises additional information indicating file sizes of the source files in the data model.

10. The system of claim 7, wherein the comparison module is functionally integrated into each of a plurality of the sub-modules.

11. The system of claim 10, wherein a plurality of the sub-modules are simultaneously operational.

12. The system of claim 7, wherein said comparison module is functionally independent of each of the sub-modules.

13. A system for establishing consistency, with respect to a data model, between sub-modules within an E-CAD tool, comprising:
means for creating a consistency database including at least one consistency indicator for each block of interest in the data model;
means for executing one of the sub-modules to perform an analysis of a current version of the data model;
means for comparing a data field value corresponding to said consistency indicator, for each block of interest, in source files in the current version of the data model being analyzed, against a corresponding said consistency indicator in the consistency database;
wherein the consistency indicator comprises timestamp information indicating at least one of a time of creation and a time of modification of one of the source files; and
means for issuing a warning indicating a possible discrepancy between data in the version of the data model being analyzed and corresponding said data in a previous said version of the data model, in response to detecting a difference between said data field value in the current version of the data model being analyzed and the corresponding said consistency indicator.

14. The system of claim 13, wherein the timestamp information indicates both a time of creation and a time of modification of one of the source files.

15. The system of claim 14, wherein the consistency indicator includes additional information indicating file sizes of the source files in the data model.

16. The system of claim 13, wherein the means for issuing a warning is functionally integrated into each of a plurality of the sub-modules.

17. The system of claim 16, wherein a plurality of the sub-modules are simultaneously operational.

18. A software product comprising instructions, stored on computer-readable media, wherein the instructions, when executed by a computer, perform steps for establishing consistency, with respect to a data model, between sub-modules within an E-CAD tool, comprising:
creating a consistency database including at least one consistency indicator for each block of interest in the data model;
executing one of the sub-modules to perform an analysis of a current version of the data model;
comparing a data field value corresponding to said consistency indicator, for each block of interest, in source files in the current version of the data model being analyzed, against a corresponding said consistency indicator in the consistency database;
wherein the consistency indicator comprises timestamp information indicating at least one of a time of creation and a time of modification of one of the source files; and
issuing a warning indicating a possible discrepancy between data in the version of the data model being analyzed and corresponding said data in a previous said version of the data model, in response to detecting a difference between said data field value in the current version of the data model being analyzed and the corresponding said consistency indicator.

19. The method of claim 18, wherein the timestamp information indicates both a time of creation and a time of modification of one of the source files.

20. The method of claim 19, wherein the consistency indicator further comprises additional information indicating file sizes of the source files in the data model.
